(19) United States
(12) Patent Application Publication
(10) Pub. No.: US 2012/0244793 A1
(43) Pub. Date: Sep. 27, 2012

(54) CONTAINER DATA CENTER

(75) Inventors: TAI-WEI LIN, Tu-Cheng (TW); ZEU-CHIA TAN, Tu-Cheng (TW)

(73) Assignee: HON HAI PRECISION INDUSTRY CO., LTD., Tu-Cheng (TW)

(21) Appl. No.: 13/084,548

(22) Filed: Apr. 11, 2011

(30) Foreign Application Priority Data
Mar. 24, 2011 (TW) 100110010

(51) Int. Cl. H05K 5/02

(52) U.S. Cl. 454/184

(57) ABSTRACT

A container data center includes a container defining a number of inlets, a number of server systems received in the container. A cold aisle is defined between the container and the server systems. The cold aisle forms a number of commutating portions each corresponding to one of the inlets. Each commutating portion includes a ventilation plate opposite to the corresponding inlet. The ventilation plate defines a number of ventilation holes.

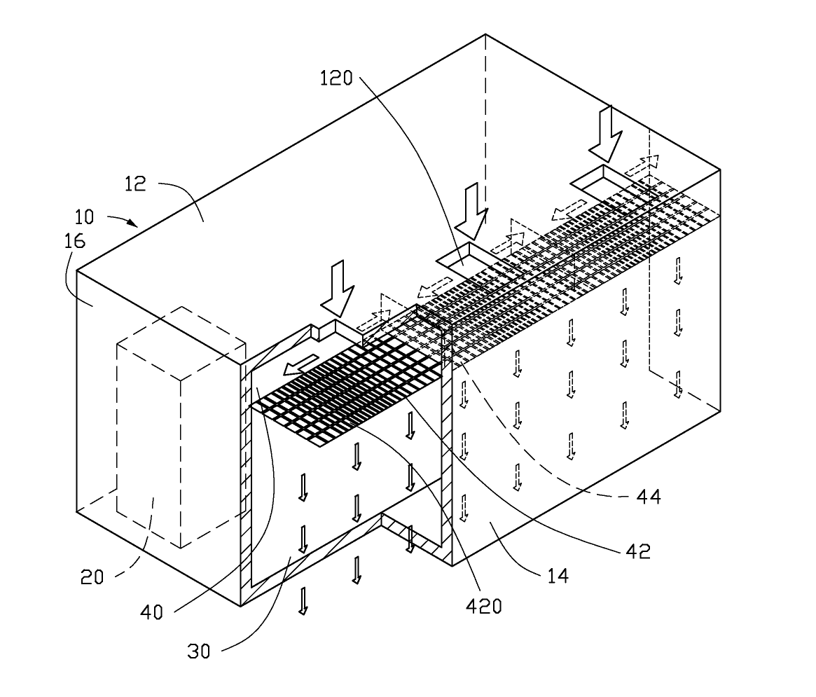

### BACKGROUND

1. Technical Field

The present disclosure relates to a container data center.

2. Description of Related Art

With an increasing heavy use of on-line applications, the need for computer data centers has increased rapidly. Data centers are centralized computing facilities that include many servers, often arranged on server racks or shelves, and one rack or shelf with some servers can be considered a server system. The server systems are received in a mobile container. During operation, server systems generate a lot of heat in the data centers, a common method for dissipating the heat is to use a cold aisle formed between a front end of the server systems and the container, cold air enters the cold aisle for server systems to dissipate the heat. However, when cold air enters the cold aisle, flows of the cold air could be strong, which can be uncomfortable for users needy of working in the cold aisle.

### BRIEF DESCRIPTION OF THE DRAWING

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

The drawing is a schematic, partially cutaway view of an exemplary embodiment of a container data center.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

Referring to the drawing, an exemplary embodiment of a container data center includes a container 10, and a plurality of server systems 20 (only one shown in the drawing) received in the container 10 and arranged in a row. A cold aisle 30 is defined between the server systems 20 and the container 10.

The container 10 is substantially rectangular and includes a top wall 12, a front wall 14, and two opposite side walls 16. The cold aisle 30 is defined between the server systems 20 and the front wall 14 of the container 10. The top wall 12 defines a plurality of inlets 120 communicating with the cold aisle 30. The cold aisle 30 forms a plurality of commutating portions 40 each corresponding to a corresponding one of the inlets 120. Each commutating portion 40 includes a ventilation plate 42 aligning with the corresponding inlet 120 and parallel to the top wall 12. The ventilation plates 42 are head-to-tail connected together. A plurality of connection plates 44 perpendicularly extends from joints of two adjacent ventilation plates 42 to be mounted to the top wall 12 of the container 10. Each commutating portion 40 is formed between two adjacent connection plates 44, or between one side wall 16 and an adjacent connection plate 44. Each inlet 120 is arranged between two adjacent connection plates 44, or between one side wall 16 and an adjacent connection plate 44. Each ventilation plate 42 defines a plurality of ventilation holes 420. Areas of the ventilation holes 420 defined in each ventilation plate 14 gradually increase from a portion of the ventilation plate 42 aligned with the inlet 120 to opposite sides of the ventilation plate 42.

In use, cold air enters the cold aisle 30 through the inlets 120. An area of a cross section of the inlet 12 is A1. An area of a cross section of the commutating portion 40 is A2. A2 is greater than A1. According to fluid continuity equation A×V=C, where A stands for an area of a cross section of cold air moving, V stands for a cold air speed, and C stands for a constant. Thus, cold air enters the inlets 120 with greater speed, after cold air has entered the commutating portions 40, the speed of cold air lowers. Moreover, the speed of cold air that aligns with the inlet 120 is faster, areas of the ventilation holes 420 defined in each ventilation plate 14 gradually increasing from the portion of the ventilation plate 42 aligned with the inlet 120 to opposite sides of the ventilation plate 4 can cause the flows of cold air to be uniform when entering the cold aisle 30.

In other embodiments, the areas of the ventilation holes 420 defined in the ventilation plate 14 gradually increase from a part of the ventilation plate 14 aligning with the inlet 120 to portions of the ventilation plate 42 around the corresponding inlet 120.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

1. A container data center comprising:
a container defining a plurality of inlets;
a plurality of server systems received in the container; and
a cold aisle defined between the container and the server systems;
wherein the cold aisle forms a plurality of commutating portions each corresponding to one of the inlets, each commutating portion comprises a ventilation plate opposite to the corresponding inlet, the ventilation plate defines a plurality of ventilation holes.

2. The container data center of claim 1, wherein the inlets are defined in a top wall of the container.

3. The container data center of claim 2, wherein the ventilation plates are head-to-tail connected together, a plurality of connection plates perpendicularly extends from joints of two adjacent ventilation plates to be mounted to the top wall of the container.

4. The container data center of claim 3, wherein the cold aisle is defined between the server systems and a front wall of the container, and each commutating portion is formed between two adjacent connection plates, or between a side wall of the container and an adjacent connection plate.

5. The container data center of claim 4, wherein each inlet is between two adjacent connection plates, or between a side wall of the container and an adjacent connection plate.

6. The container data center of claim 1, wherein areas of the ventilation holes defined in each ventilation plate gradually increase from a part of the ventilation plate aligning with the corresponding inlet to opposite sides of the ventilation plate.

7. The container data center of claim 1, wherein areas of the ventilation holes defined in each ventilation plate gradually increase from a part of the ventilation plate aligning with the inlet to portions of the ventilation plate around the corresponding inlet.
